(19) United States
(12) Patent Application Publication
(10) Pub. No.: US 2007/0279967 A1
(43) Pub. Date: Dec. 6, 2007

(54) High density magnetic memory cell layout for spin transfer torque magnetic memories utilizing donut shaped transistors

(76) Inventors: Xiao Luo, Cupertino, CA (US); Lien-Chang Wang, Fremont, CA (US)

Correspondence Address: STRATEGIC PATENT GROUP, P.C., P.O. BOX 1329, MOUNTAIN VIEW, CA, 94042, US

(21) Appl. No.: 11/436,446

(22) Filed: May 18, 2006

(51) Int. Cl. H01L 29/76; H01L 29/94; G11C 11/00; G11C 11/14; H01L 31/00

(52) U.S. Cl. 365/158; 365/171; 257/401

(57) ABSTRACT

A method and system for providing and using a magnetic storage cell and magnetic memory is described. The method and system include providing a magnetic element and providing a selection device. The magnetic element is programmable to a first state by a first write current driven through the magnetic element in a first direction and to a second state by a second write current driven through the magnetic element in a second direction. The selection device is connected with the magnetic element. The selection device includes a gate having an aperture therein. The selection device is configured such that the first write current and second write current are provided to the magnetic element across the aperture.

### FIELD OF THE INVENTION

The present invention relates to magnetic memory systems, and more particularly to a method and system for providing a memory, magnetic storage cells and selection devices having enhanced current.

### BACKGROUND OF THE INVENTION

FIGS. 1A and 1B depict side and plan views of a conventional magnetic storage cell 10, which may be used in a conventional magnetic random access memory (magnetic RAM) that utilizes spin transfer based switching. The conventional magnetic storage cell 10 includes a magnetic element 12 and a conventional selection device 14. The conventional selection device 14 is typically a transistor, such as a CMOS transistor, and has a conventional gate 16, a conventional source 18, and a conventional drain 20. The magnetic element 12 is connected with the conventional drain 20 by the conventional conductive plug 22.

The conventional magnetic element 12 is configured to be changeable between high and low resistance states by driving a current through the conventional magnetic element 12. The current is spin polarized when passing through the magnetic element 12 and changes the state of the magnetic element 12 by the spin transfer effect. For example, the magnetic element 12 may be a magnetic tunnel junction (MTJ) configured to be written using the spin transfer effect. Typically, this is achieved by ensuring that the magnetic element 12 has, for example, a sufficiently small cross-sectional area as well as other features desirable for switching using the spin transfer effect. When the current density is sufficiently large, the current carriers driven through the magnetic element 12 may impart sufficient torque to change the state of the magnetic element 12. When the write current is driven in one direction, the state may be changed from a low resistance state to a high resistance state. When the write current is driven in the opposite direction, the state may be changed from a high resistance state to a low resistance state. For example, current driven from the source 18 across the gate 16 to the drain 20, then through the magnetic element 12 write the magnetic element to a first state, such as the high resistance state. Current driven from the magnetic element 12 and drain 20 to the source 18 would write the magnetic element 12 to the second state, such as the low resistance state.

FIG. 2 depicts the conventional magnetic storage cell 10 in a portion of a conventional magnetic random access memory (magnetic RAM) 30. Also shown are conventional word (gate) lines 32 that form the conventional gate 16 for each conventional selection transistor 14 (not separately depicted in FIG. 2), conventional source lines 34 connected with the conventional source 18, conventional bit lines 36 connected with the magnetic elements 12, and isolation structures 38 that electrically isolate the cells. Thus, each gate has a width of L. As can be seen in FIG. 2, each of the conventional magnetic storage cells 10 has its own conventional source line 34. In order to program the magnetic element 12 to a first state, one of the word lines 32 is high, the conventional source line 34 may be connected with a supply voltage, while the conventional bit line 36 is connected with ground, so that there is large enough current flowing from the source line to the bit line. To program the conventional magnetic element 12 to a second state, the conventional source line 34 may be connected with ground, while the conventional bit line 36 is connected with the supply voltage. To read the conventional magnetic RAM 30, assuming one of word lines is high, the conventional bit line 36 may be connected with a sense amplifier while the conventional source line 34 is connected to ground. A read current is provided through the magnetic element 12 for the read operation. However, the read current is not large enough to change the state of the magnetic element 12.

FIG. 3 depicts the conventional magnetic storage cell 10 in a portion of another conventional magnetic RAM 30′. Also shown are conventional word lines 32′ that form the conventional gates 16 for each conventional selection transistor 14 (not separately indicated in FIG. 3), conventional shared source lines 34′, conventional bit lines 36′ connected with the magnetic elements 12, and isolation structures 38′ that electrically isolate the cells. Thus, each gate 16 has a width of L′ in the memory 30′. As can be seen in FIG. 3, a pair of the conventional magnetic storage cells 10 shares a conventional source line 34′. In order to program the magnetic element 12 to a first state, the conventional source line 34′ may be connected with a supply voltage, while the conventional bit line 36′ is connected with ground. To program the conventional magnetic element 12 to a second state, the conventional source line 34′ may be connected with ground, while the conventional bit line 36′ is connected with the supply voltage. To read the conventional magnetic RAM 30′, the conventional bit line 36′ may be connected with a lower voltage while the conventional source line 34′ is connected to ground. The lower voltage is insufficient to drive a current large enough to change the state of the magnetic element 12.

The conventional magnetic RAMs 30 and 30′ utilize a write current driven through the magnetic element 12 in order to program data to the conventional magnetic storage cell 10. Thus, the conventional magnetic RAMs 30 and 30′ use a more localized phenomenon in programming the conventional magnetic element 12. Unlike a conventional MRAM that switches its state by applying magnetic fields, the conventional magnetic RAMs 30 and 30′ do not suffer from a half select write disturb problem. Moreover, for higher density memories, and smaller individual magnetic elements 12, a lower current corresponds to the same current density as a larger magnetic element. Thus, the current required to write to the conventional magnetic RAMs 30 and 30′ decrease with decreasing size, which is desirable. This trend is distinct from a conventional MRAM that switches its state by applying magnetic fields, which requires a significantly higher write current at lower sizes. For example, for a conventional magnetic element 12 having a size less than approximately two hundred nanometers, the conventional magnetic RAM 1 utilizes a lower write current than the write current used to generate a write field for a conventional MRAM that switches its state by applying magnetic fields. In particular, the unit area of the conventional magnetic storage cell 10 might be greatly reduced down to six to eight F², where F is the critical dimension of unit cell size, when the parameters, including materials and processing, are optimized.

Although the conventional magnetic RAMs 30 and 30′ generally utilize a lower current and a more localized programming scheme, one of ordinary skill in the art will readily recognize that the use of the conventional magnetic RAMs 30 and 30′ in higher density memory applications may be limited by various factors. For example, the size of a conventional magnetic storage cell 10 may primarily be determined by the write current used to switch the conventional magnetic element 12, and thus the size of the conventional selection transistor 14. The dominant factor today that limits the size of the conventional magnetic storage cell 10 is the width of the selection transistor 14. In the memories 30 and 30′, this width, L or L′ in FIGS. 2 and 3, is determined by the width of the gate 16. The width L or L′ of conventional selection transistor 14 is proportional to the drive current that can be passed through the conventional selection transistor 14. Thus, to provide higher current needed for the writing process, the conventional selection transistor 14 is typically scaled up. However, the increased size of the conventional selection device 14 increases the size of the cell 10. As a result, the memory density may be reduced.

Accordingly, what is desired is a method and system for providing and utilizing storage cells that may employ spin transfer based switching, which may be suitable for a higher density magnetic memory. The present invention addresses such a need.

### BRIEF SUMMARY OF THE INVENTION

The present invention provides a method and system for providing and using a magnetic storage cell and magnetic memory. The method and system comprise providing a magnetic element and providing a selection device. The magnetic element is programmable to a first state by a first write current driven through the magnetic element in a first direction and to a second state by a second write current driven through the magnetic element in a second direction. The selection device is connected with the magnetic element. The selection device includes a gate having an aperture therein. The selection device is configured such that the first write current and second write current are provided to the magnetic element across the aperture.

According to the method and system disclosed herein, the present invention provides a mechanism for programming and reading a magnetic memory that may provide an enhanced write current.

### BRIEF DESCRIPTION OF SEVERAL VIEWS OF THE DRAWINGS

FIGS. 1A and 1B are side views and plan views of a conventional magnetic storage cell.

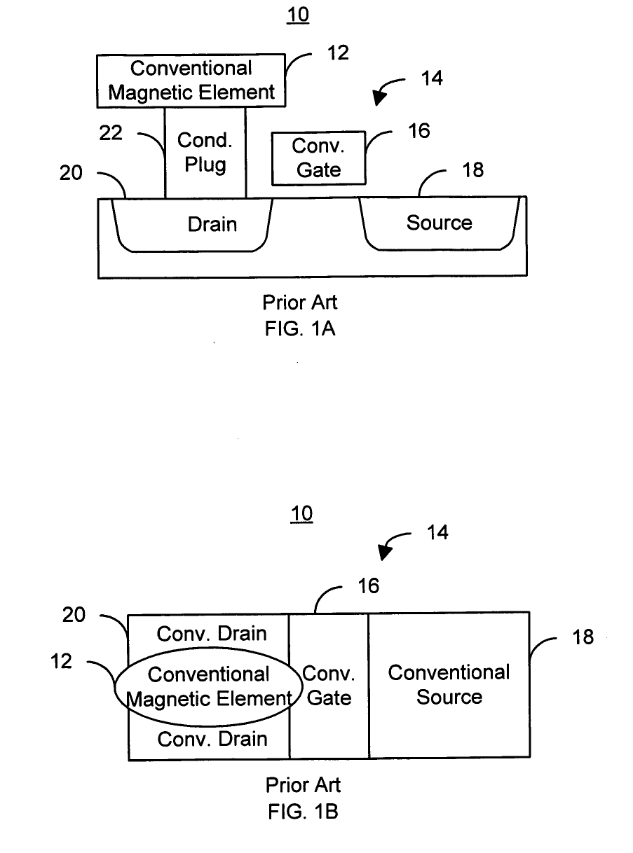

FIG. 2 is a diagram of a portion of a conventional magnetic RAM using the conventional magnetic storage cell.

FIG. 3 is a diagram of a portion of another conventional magnetic RAM using the conventional magnetic storage cell.

FIGS. 4A-B are diagrams depicting plan and side views of one embodiment of a magnetic storage cell in accordance with the present invention.

FIG. 5 is a diagram of one embodiment of a portion of a magnetic memory in accordance with the present invention using one embodiment of a magnetic storage cell in accordance with the present invention.

FIGS. 6A-6B are diagrams of one embodiment of a portion of a magnetic memory in accordance with the present invention using one embodiment of a magnetic storage cell in accordance with the present invention during a write operation.

FIG. 7 is a flow chart depicting one embodiment of a method for providing a portion of a magnetic memory in accordance with the present invention using one embodiment of a magnetic storage cell in accordance with the present invention.

FIG. 8 is a flow chart depicting one embodiment of a method for utilizing a magnetic memory in accordance with the present invention using one embodiment of a magnetic storage cell in accordance with the present invention.

### DETAILED DESCRIPTION OF THE INVENTION

The present invention relates to a magnetic memory. The following description is presented to enable one of ordinary skill in the art to make and use the invention and is provided in the context of a patent application and its requirements. Various modifications to the preferred embodiments and the generic principles and features described herein will be readily apparent to those skilled in the art. Thus, the present invention is not intended to be limited to the embodiments shown, but is to be accorded the widest scope consistent with the principles and features described herein.

The present invention provides a method and system for providing and using a magnetic storage cell and magnetic memory. The method and system comprise providing a magnetic element and providing a selection device. The magnetic element is programmable to a first state by a first write current driven through the magnetic element in a first direction and to a second state by a second write current driven through the magnetic element in a second direction. The selection device is connected with the magnetic element. The selection device includes gate which has an aperture therein. The magnetic element is configured such that the first write current and second write current are provided to the magnetic element across the aperture.

The present invention is described in the context of particular magnetic memories having certain components, such magnetic storage cells having magnetic elements and particular components. One of ordinary skill in the art will readily recognize that the present invention is consistent with the use of magnetic memories having other and/or additional components consistent with the present invention. The method and system in accordance with the present invention are also described in the context of reading from, writing to, or providing a single magnetic storage cell. However, one of ordinary skill in the art will readily recognize that the method and system can be extended to read from, write to, and/or provide multiple magnetic storage cells substantially in parallel. The present invention is described in the context of certain memories. However, one of ordinary skill in the art will readily recognize that the present invention is compatible with memories and other devices not inconsistent with the present invention. The present invention is also described in the context of particular methods. One of ordinary skill in the art will, however, readily recognize that other methods having different and/or additional steps consistent with the present invention may be used.

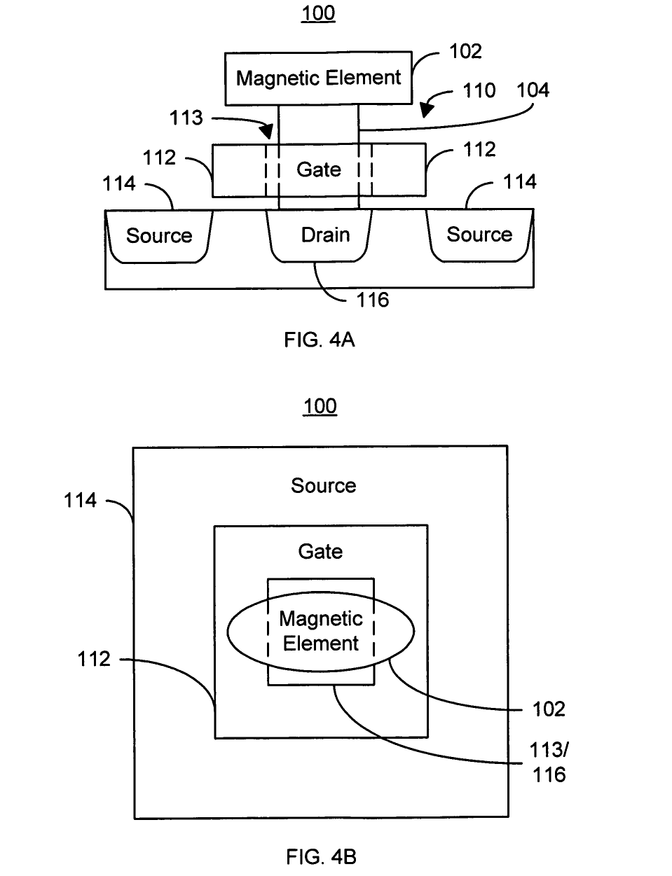

To more particularly describe the method and system in accordance with the present invention, refer to FIGS. 4A and 4B, depicting one embodiment of a magnetic storage cell 100 in accordance with the present invention. FIG. 4A depicts a side view of the magnetic storage cell 100, while FIG. 4B is a plan view of the magnetic storage cell 100. The magnetic storage cell 100 includes a magnetic element 102, a selection device 110 and a conductor (contact/via) 104 that connects the magnetic element 102 with the selection device 110. The magnetic element 102 is configured to be changeable between high and low resistance states by driving a current through the conventional magnetic element 102. The current is spin polarized when passing through the magnetic element 102 and changes the state of the magnetic element 102 by the spin transfer effect. For example, the magnetic element 102 may be a MTJ configured to be written using the spin transfer effect. Typically, this is achieved by ensuring that the magnetic element 102 has, for example, a sufficiently small cross-sectional area as well as other features desirable for switching using the spin transfer effect. When the current density is sufficiently large, the current carriers driven through the magnetic element 102 may impart sufficient torque to change the state of the magnetic element 102. When the write current is driven in one direction, the state may be changed from a low resistance state to a high resistance state. When the write current is driven in the opposite direction, the state may be changed from a high resistance state to a low resistance state.

The selection device 110 is a donut selection device. The donut selection device 110 is preferably a transistor, such as a CMOS transistor. The selection device 110 thus preferably includes a gate 112, a source 114, and a drain 116. The gate 112 has an aperture 113 therein. The drain 116 and, in a preferred embodiment, the conductor 104 are aligned with the aperture 113. In a preferred embodiment, the magnetic element 102 is aligned with the aperture 113. However, in other embodiments, the magnetic element 102 may not be aligned with the aperture 113. The magnetic element 102 and the donut selection device 110 are configured such that the write currents are provided across the aperture 113. Because of the presence of the aperture 113, the donut selection device 110 is termed a donut selection device 110. In addition, although the gate 112 and aperture 113 are depicted as having a square or rectangular shape perimeter in the plan view, another shape and/or an aperture of another shape may be used.

In operation, the magnetic element 102 may be programmed by connecting the source 114 to a high (e.g. supply) voltage and the magnetic element 102 to ground to write the magnetic element to one state. Thus, current is driven across the gate 112 from its outer perimeter across the inner edges gate 112 forming the aperture 116 (hereinafter simply termed “across” the aperture) and to the magnetic element 102. Stated differently, the current may flow to the drain 116, and thus the magnetic element 102, from all sides of the aperture 113. The magnetic element 102 may be programmed to another state by connecting the source 114 to a low voltage (e.g. ground) and the magnetic element 102 to a high voltage (e.g. supply voltage). Thus, current is driven from the magnetic element 102, across the aperture 113, and across the gate 112 from its inner perimeter to the source 114 at the outer perimeter. The current may flow from the drain 116, and thus the magnetic element 102, to the source 114 from all sides of the aperture 113. During reading, a lower current is driven through the magnetic element 102 either from the source 114 to the drain 116 and the magnetic element 102, or vice versa.

The donut selection device 110 is capable of supporting a larger write current than a conventional transistor of the same size. Because current is driven across the aperture 113, the effective width of the gate 112 of the transistor 110 is increased for a given cell 100 area. As stated above, the current that may be driven through a magnetic storage cell 100 varies as the gate width. Consequently, a higher driving current may be achieved for a given area of the magnetic storage cell 100. For example, due to the layout of the donut selection device 110, the size of the unit cell is believed to be approximately twenty-five F². A magnetic storage cell 100 of this size may provide approximately 300 uA driving current for a 90 nm technology node. Thus, a reduced cell size and, therefore, increased memory density may be achieved.

In addition, the magnetic storage cell 100 may have improved signal. It is noted that when reading the state of a magnetic element 102, the output signal is closely related to the resistance of the donut selection device I 10. This is because the magnetic element 102 is connected in series with the donut selection device 110, essentially forming a voltage divider. As a result, the higher the resistance of the donut selection device 110, the lower the signal from the magnetic element 102. Because the effective gate width of the donut selection device 110 is longer than that of a conventional transistor for a given magnetic storage cell size, the resistance of the donut selection device 110 is lower. Consequently, an improved signal in the form of a higher current difference between high and low resistance states of the magnetic element 102 may be achieved. This high delta current enables high speed reading and could essentially reduce the error rate of reading. Thus, the magnetic storage cell 100 may have a more compact size, may be capable of supporting a higher write current for a given size, an enhanced read signal that allows for a higher memory speed during operation and improved data integrity.

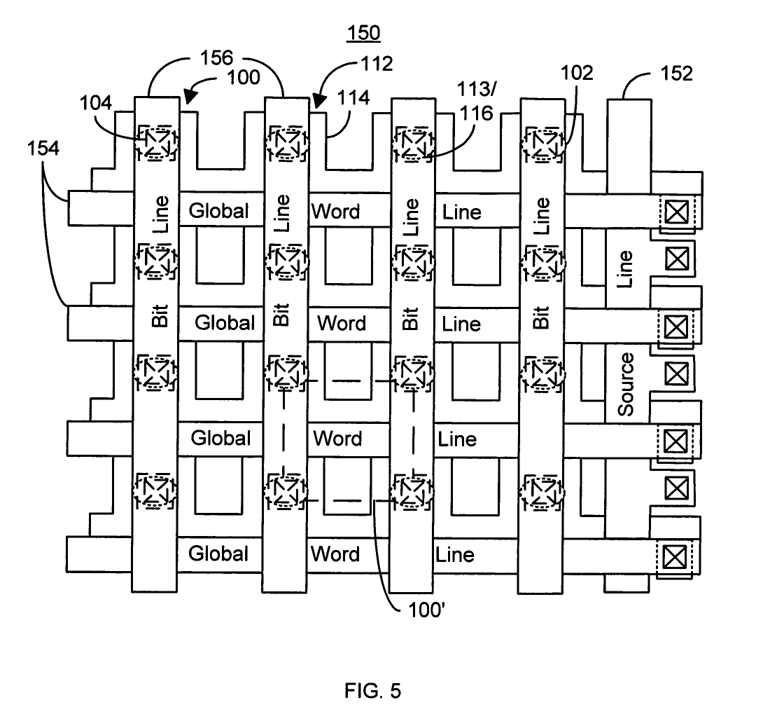

FIG. 5 is a diagram of one embodiment of a portion of a magnetic memory 150 in accordance with the present invention using one embodiment of a magnetic storage cell 100 in accordance with the present invention. The magnetic memory 150 is depicted as including a particular number of magnetic storage cells 100. However, one of ordinary skill in the art will readily recognize that the magnetic memory 150 could include another number or storage cells. The magnetic storage cells 100 are arranged into a number of rows and columns. However, one of ordinary skill in the art will readily recognize that the magnetic memory 150 could include another number of rows and/or columns.

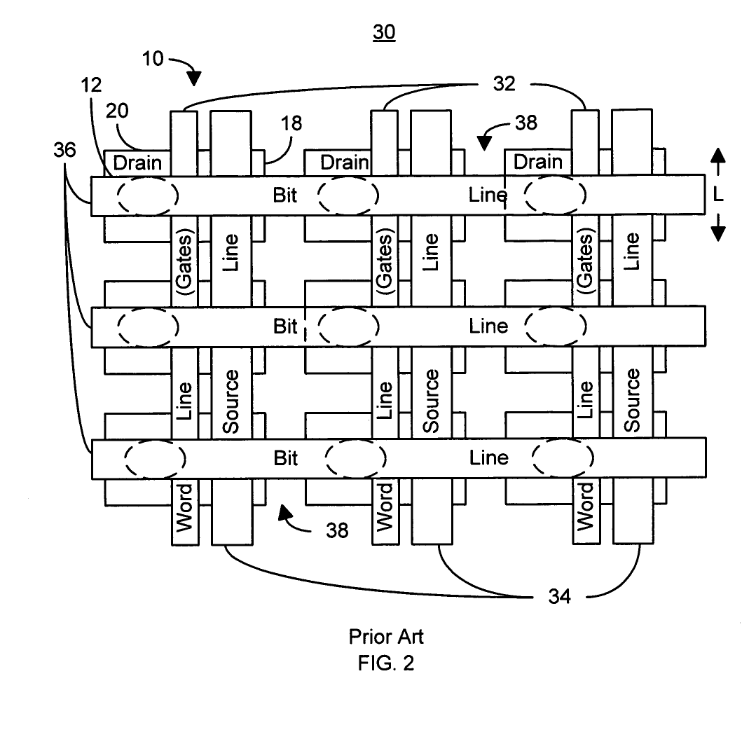

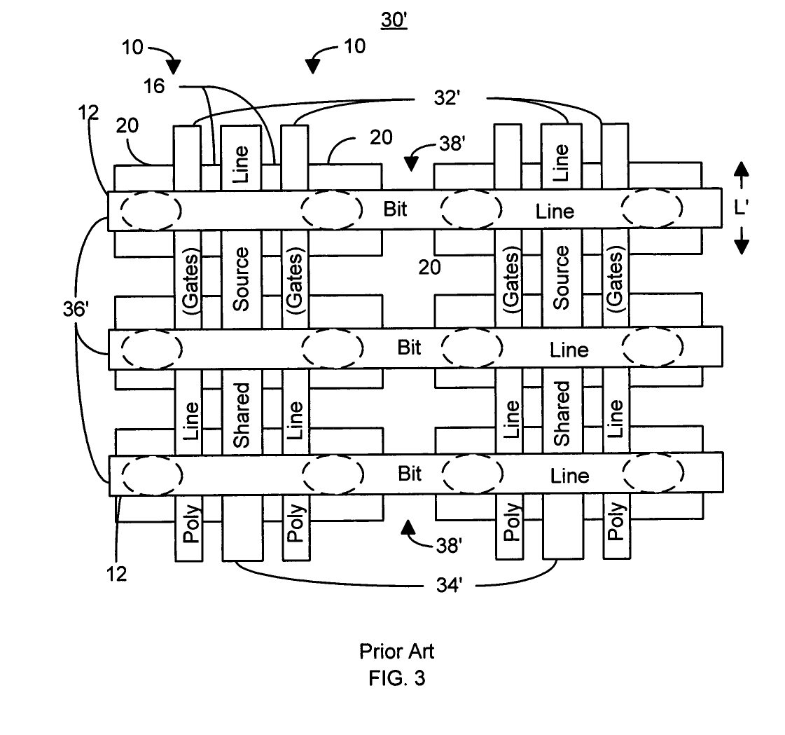

In addition to the magnetic storage cells 100, the magnetic memory 150 includes a source line 152, global word lines 154, and bit lines 156. The source line 152 is connected with the sources of the magnetic storage cells 100. Thus, in the embodiment shown, the sources 114 of the donut selection devices 110 are connected together and share the source line 152. The ability of a group of the magnetic storage cells 100 to share the source line 152 may further increase the density of the magnetic memory 150. In addition, isolation structures, such as the structures 38/38′ in the conventional magnetic RAMs depicted in FIGS. 2-3 may be eliminated. Instead, the spacing due to the gates 112 of the donut selection devices 110 may serve to isolate different storage cells 100.

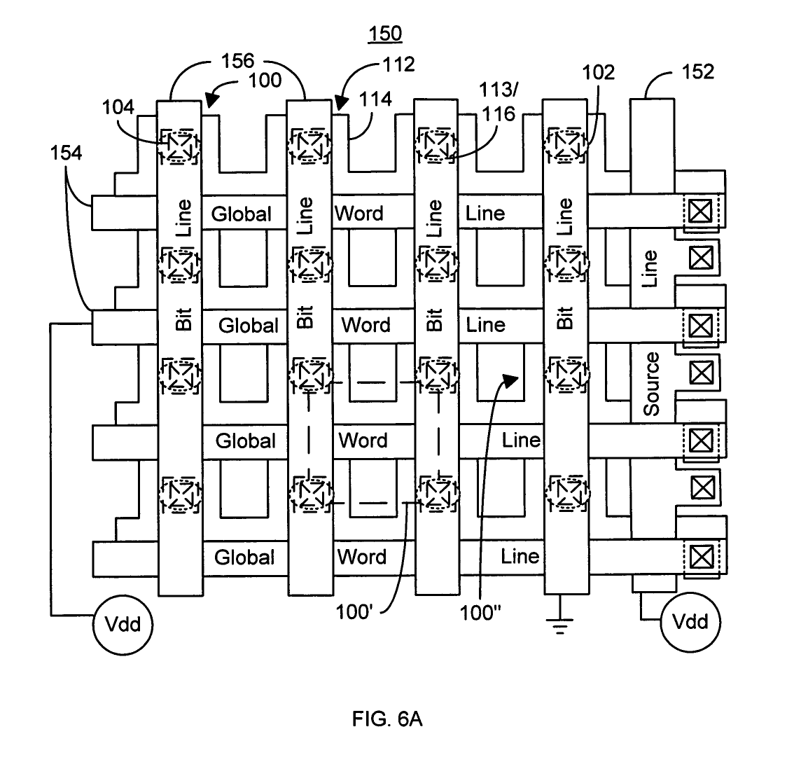

In operation, one or more magnetic storage cells 100 may be programmed by connecting the source line 152 to a high (e.g. supply) voltage and the bit line(s) 156 to ground to write the magnetic element to one state. At the same time, the desired row(s) are enabled by connecting the desired global word line(s) 154 to a high voltage. FIG. 6A depicts the magnetic memory 150 during such a write operation. Because the global word line(s) 154 are driven high, the appropriate donut selection device(s) 110 may be turned on. Thus, current is driven across the gate 112 from its outer perimeter across the aperture and to the magnetic element 102. The magnetic element 102 may be programmed to another state by connecting the source line 152 to a low voltage (e.g. ground) and the bit line(s) 156 to a high voltage (e.g. supply voltage) while the desired global word line 154 is driven high. FIG. 6B depicts the magnetic memory 150 during such a write operation. Thus, current is driven from the magnetic element 102, across the aperture 113, and across the gate 112 from its inner perimeter to the source 114 at the outer perimeter. During reading, a lower current is driven through the magnetic element 102 either from the source 114 to the drain 116 and the magnetic element 102, or vice versa.

Thus, the magnetic memory 150 shares the benefits of the magnetic storage cell 100. In particular, the magnetic memory utilizes donut selection devices 110 having a longer gate width for a given area of the storage cell 100. Consequently, a higher density memory capable of using a higher write current as well as improved reading characteristics may be achieved. Furthermore, the isolation between unit cells 100′ is eliminated and replaced by the gates 112. Thus, memory density might be further increased. In addition, multiple storage cells 100 may share the source line 152. As a result, a further increase in memory density may be provided. The global word line 154 may, in a preferred embodiment, be made of metal. The global word line 154 may thus be used to provide a higher speed for the donut selection devices 110. The global word line 154 may also improve performance of the gate 112, which is preferably made from high resistance poly-silicon.

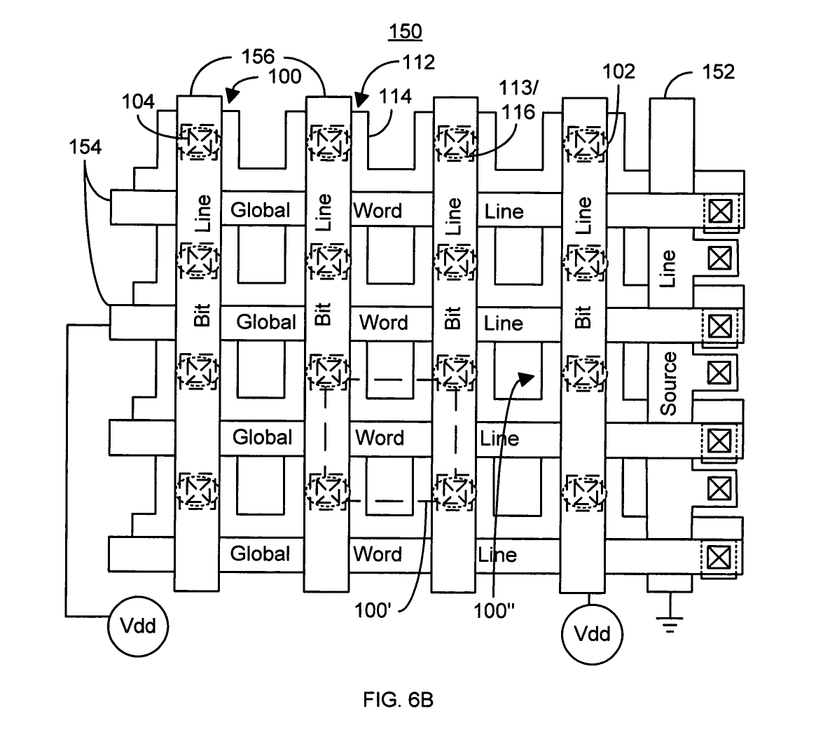

FIG. 7 is a flow chart depicting one embodiment of a method 200 for providing a portion of a magnetic memory 150 in accordance with the present invention using one embodiment of a magnetic storage cell in accordance with the present invention. The method 200 is described in the context of the magnetic memory 150. However, one of ordinary skill in the art will readily recognize that another analogous magnetic memory (not shown) might be used. In addition, one of ordinary skill in the art will readily recognize that for simplicity, some steps may be omitted.

The donut selection device 110 is provided for each magnetic storage cell 100 in the memory, via step 202. Step 202 includes providing the sources 114 for the magnetic storage cells 100. The sources 114 may be interconnected, for example by doping interconnecting regions of a substrate. Step 202 also includes providing the drains 116 and the gates 112 having apertures 113. Other interconnects, such as the source line 152 and word line 154, may be provided, via step 204. The conductor (contact/via) 104 is provided, via step 206. In a preferred embodiment, the conductor 104 is a metal plug provided in the aperture 113 and is electrically connected to the drain 116 of each storage cell 100. The magnetic element 102 is provided, via step 208. Step 208 includes providing the magnetic element 102 that is capable of being written by driving current(s) through the magnetic element. The interconnects are provided, via step 210. Thus, step 210 may provide bit lines 156. Note that in a preferred embodiment, other interconnect layers such as word lines 154 and source line 152 were previously provided. Processing of the magnetic memory 150 may then be completed.

Thus, using the method 200, a magnetic memory 150 which includes storage cells 100 may be provided. Consequently, the benefits of the memory 150 and storage cells 10 may be achieved.

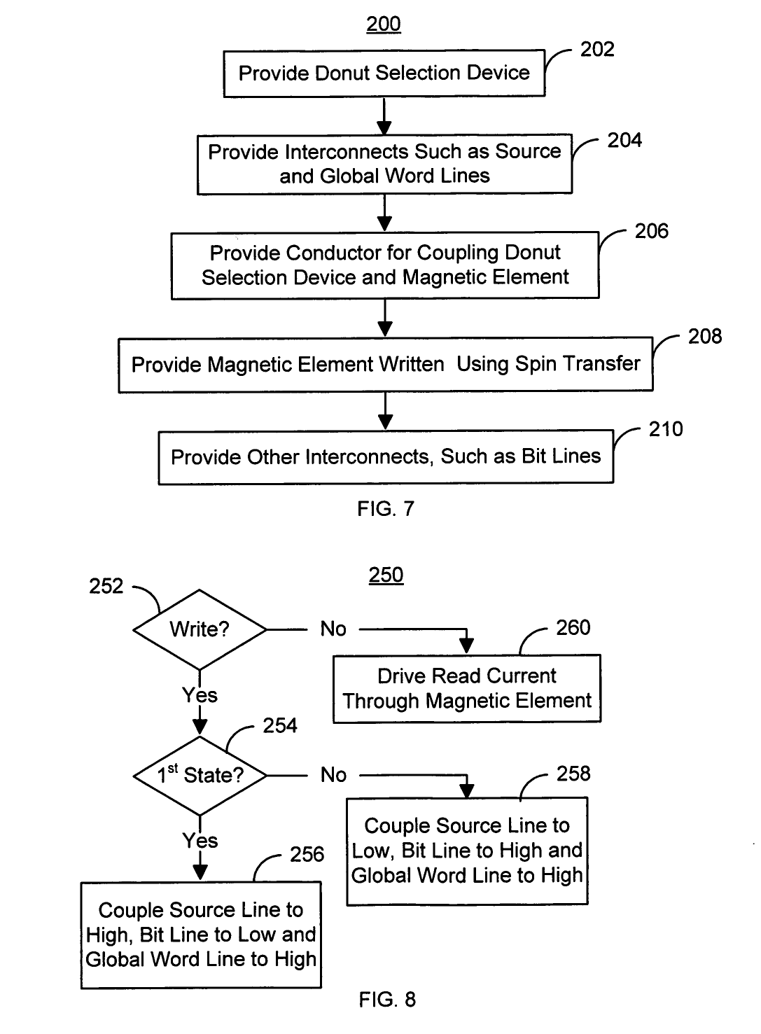

FIG. 8 is a flow chart depicting one embodiment of a method 250 for utilizing a magnetic memory in accordance with the present invention using one embodiment of a magnetic storage cell in accordance with the present invention. The method 250 is described in the context of the magnetic memory 150. However, one of ordinary skill in the art will readily recognize that another analogous magnetic memory (not shown) might be used. In addition, one of ordinary skill in the art will readily recognize that for simplicity, some steps may be omitted.

It is determined whether the magnetic element is to be programmed, via step 252. If so, then it is determined whether the magnetic element is to be programmed into a first state, via step 254. If so, then the source line 152 is connected to a high (e.g. supply) voltage and the bit line(s) 156 is to ground, via step 256. In addition, step 256 connects the desired global word line(s) 154 to a high voltage to enable the desired row(s). Because the global word line(s) 154 are driven high in step 256, the appropriate donut selection device(s) 110 may be turned on.

If it is determined in step 254 that the magnetic element is not to be programmed into the first state, then the magnetic element 102 is to be programmed into a second state. Thus, the source line 152 is connected to a low voltage (e.g. ground) and the bit line(s) 156 is connected to a high voltage (e.g. supply voltage), via step 258. Also in step 258, the desired global word line 154 is driven high. Thus, current is driven from the magnetic element 102, across the aperture 113, and across the gate 112 from its inner perimeter to the source 114 at the outer perimeter.

If it is determined in step 252 that the magnetic element 102 is not to be programmed, then a read operation ensues. Thus, a lower current is driven through the magnetic element 102, via step 260. Step 260 may either drive from the source 114 to the drain 116, or vice versa. Thus, step 260 may include connecting the source 114 to a high voltage and the magnetic element 102 to ground, or vice versa. However the voltage to which the source 114 or magnetic element 102 are connected is lower than for a write operation. Consequently, the read current that flows in step 260 is insufficient to change the state of the magnetic element 102.

Thus, magnetic storage cell 100 and magnetic memory 150 may be written using a more localize phenomenon, at a higher write current, with lower cell size and improved read characteristics. Consequently, performance of the magnetic memory 150 and storage cell 100 may be improved.

A method and system for providing and using a magnetic memory having an improved read and write margins has been disclosed. The present invention has been described in accordance with the embodiments shown, and one of ordinary skill in the art will readily recognize that there could be variations to the embodiments, and any variations would be within the spirit and scope of the present invention. Accordingly, many modifications may be made by one of ordinary skill in the art without departing from the spirit and scope of the appended claims.

We Claim:

1. A magnetic storage cell comprising:
a magnetic element programmable to a first state by a first write current driven through the magnetic element in a first direction and to a second state by a second write current driven through the magnetic element in a second direction; and
a selection device connected with the magnetic element, the selection device including a gate having an aperture therein, the selection device being configured such that the first write current and second write current are across the aperture.

2. The magnetic storage cell of claim 1 wherein the selection device includes a source and a drain, the drain being aligned with the aperture.

3. The magnetic storage cell of claim 2 further comprising:
a conductor connecting the selection device with the magnetic element.

4. A magnetic memory comprising:
plurality of magnetic storage cells, each of the plurality of magnetic storage cells including a magnetic element and a selection device connected with the magnetic element, the magnetic element being programmable to a first state by a first write current driven through the magnetic element in a first direction and to a second state by a second write current driven through the magnetic element in a second direction, the selection device including a gate having an aperture therein, the selection device being configured such that the first write current and second write current are provided to the magnetic element across the aperture;
a plurality of word lines, each of the plurality of word lines connected with the gate for each of a portion of the plurality of selection devices.

5. The magnetic memory of claim 4 wherein the selection device includes a source and a drain, the drain being aligned with the aperture.

6. The magnetic memory of claim 5 wherein each of the magnetic storage cells further includes a conductor connecting the drain with the magnetic element.

7. The magnetic memory of claim 5 further comprising:
a plurality of source lines, each of the plurality of source lines connected with the source of the selection device of a first portion of the plurality of magnetic storage cells.

8. The magnetic memory of claim 7 further comprising:
a plurality of bit lines connected with the magnetic element of each of a second portion of the plurality of magnetic storage cells.

9. The magnetic memory of claim 8 wherein a portion of the plurality of bit lines correspond to a source line of the plurality of source lines.

10. The magnetic memory of claim 9 wherein a third portion of the plurality of magnetic storage cells connected with at least two of the plurality of bit lines share the source line of the plurality of source lines.

11. The magnetic memory of claim 4 further comprising:
a plurality of bit lines connected with the magnetic element of each of a portion of the plurality of magnetic storage cells.

12. The magnetic memory of claim 4 wherein the selection device includes a transistor.

13. A magnetic memory comprising:
plurality of magnetic storage cells arranged in an array including a plurality of rows and a plurality of columns, each of the plurality of magnetic storage cells including a magnetic element, a selection transistor, and a conductor connecting the selection transistor with the magnetic element, the magnetic element being programmable in a first state by a first write current driven through the magnetic element in a first direction and in a second state by a second write current driven through the magnetic element in a second direction, the selection device including a gate having an aperture therein, the magnetic element being aligned with the aperture, the gate being configured such that the first write current and second write current are provided to the magnetic element across the aperture;
a plurality of word lines aligned with the plurality of rows, each of the plurality of word lines connected with the gate for the selection transistor of each of a first portion of the plurality of storage cells;
a plurality of bit lines aligned with the plurality of columns, each of the plurality of bit lines connected with the magnetic element of a second portion of the plurality of storage cells;
a plurality of source lines, each of the plurality of source lines corresponding to a portion of the plurality of columns, the portions of the plurality of columns including more than one column; each of the plurality of source lines being connected with the source of the selection transistor in a third portion of the plurality of storage cells, the third portion of the plurality of storage cells residing in multiple rows and multiple columns.

14. A method for utilizing a magnetic storage cell including a magnetic element and a selection device connected with the magnetic element, the magnetic element being programmed to a first state by a first write current driven through the magnetic element in a first direction and to a second state by a second write current driven through the magnetic element in a second direction, the selection device including a gate, the method comprising:
driving the first current across the gate and through the magnetic element to program at least a first state, the gate having an aperture therein, the magnetic element being aligned with the aperture, the driving further including providing the first current across the aperture and to the magnetic element from a plurality of directions when the first current is driven through the magnetic element; and
driving the first current through the magnetic element and across the gate to program at least a second state, the second current being provided from the magnetic element across the aperture and to the gate in the plurality of directions when the second current is driven through the magnetic element.

15. The method of claim 14 wherein the selection device includes a source and a drain, the drain being aligned with the aperture.

16. The method of claim 15 wherein the magnetic storage cell further includes a conductor connecting the drain with the magnetic element.

17. A method for utilizing a magnetic memory, the magnetic memory including a plurality of magnetic storage cells, each of the plurality of magnetic storage cells including a magnetic element, a selection device, and a conductor connecting the selection device with the magnetic element, the magnetic element being programmed by a first write current driven through the magnetic element in a first direction and a second write current driven through the magnetic element in a second direction, the selection device including a gate, the method comprising:
driving the first current across the gate and through the magnetic element to program at least a first state in each of a first portion of the plurality of magnetic storage cells, the gate having an aperture therein, the magnetic element being aligned with the aperture such that the first current is provided to the magnetic element from a plurality of directions when the first current is driven through the magnetic element; and
driving the second current through the magnetic element and across the gate to program at least a second state in each of a second portion of the plurality of magnetic storage cells, the second current being provided from the magnetic element to the gate in the plurality of directions when the second current is driven through the magnetic element.

18. The method of claim 17 wherein the selection device includes a source and a drain, the drain being aligned with the aperture.

19. The method of claim 18 wherein the conductor connects the drain with the magnetic element.

20. The method of claim 19 further comprising:
a plurality of source lines, each of the plurality of source lines connected with the source of the selection device of a first portion of the plurality of magnetic storage cells.

21. The method of claim 20 further comprising:
a plurality of bit lines connected with the magnetic element of each of a second portion of the plurality of magnetic storage cells.

22. The method of claim 21 wherein a portion of the plurality of bit lines correspond to a source line of the plurality of source lines.

23. The method of claim 22 wherein a third portion of the plurality of magnetic storage cells connected with at least two of the plurality of bit lines share the source line of the plurality of source lines.

24. The method of claim 18 further comprising:
a plurality of bit lines connected with the magnetic element of each of a portion of the plurality of magnetic storage cells.

25. The method of claim 24wherein the selection device includes a transistor.
